(19) United States
(12) Patent Application Publication
(10) Pub. No.: US 2002/0068377 A1
(43) Pub. Date: Jun. 6, 2002

(54) Method of forming a film of a semiconductor device

(76) Inventors: Taizo Oku, Tokyo (JP); Noboru Tokumasu, Tokyo (JP); Kazuo Maeda, Tokyo (JP)

Correspondence Address: LORUSSO & LOUD, 3137 Mount Vernon Avenue, Alexandria, VA, 22305, US

(21) Appl. No.: 10/050,911

(22) Filed: Jan. 22, 2002

Related U.S. Application Data
(62) Division of application No. 09/448,903, filed on Nov. 29, 1999, now abandoned.

(30) Foreign Application Priority Data
Dec. 1, 1998 (JP) 10-341777

(51) Int. Cl. H01L 21/00; H01L 21/302

(52) U.S. Cl. 438/105; 438/692

(57) ABSTRACT

This invention concerns with such methods to form the film of semiconductor device, without degrading any desirable characteristics of the device, that enables the endpoint detection pertaining to the polishing process of either the conductive film or the insulating film. This invention includes such three processing steps: (1) to form DLC film 3, (2) to an form insulating film 6 upon a DLC film 3, (2) to expose a plasma gas containing fluorine to the DLC film 3, (3) to an form insulating film 6 upon the DLC film 3, and (4) to polish the insulating film 6 by means of Chemical Mechanical Polishing (CMP), and to stop the polishing at the point in time when the DLC film 3 appears at the surface of the substrate.

### BACK GROUND OF THE INVENTION

1. Field of the Invention

This invention relates to a method to form a DLC film used as an etching stopping film or a polishing stopping film for forming a semiconductor device.

2. Description of the Prior Art

In recent years, industry's need for higher speed, larger integration semiconductor device is intense. Accordingly, the innovations in process technologies for producing more fine and/or multilevel interconnections are being sought.

In order to produce such semiconductor device that have very fine and/or multilevel interconnection, a planarization technique which involves an interlayer insulating film or metal embedded in the insulating film is essential.

Chemical Mechanical Polishing (CMP), to fill up conducting substance for interconnection into grooves of the insulating film, and/or to fill up insulating substance for isolation into trenches of the substrate, is one of the planarization techniques.

An example of the implementation of such planarization technique is a Cu-embedded interconnection technique by means of CMP. The Cu-embedded interconnection technique is regarded a promising material for interconnection of integrated circuit (IC) because of the following two reasons:

(1) it is highly reliable in operations at high current densities, and

(2) it can shorten the signal-propagation-delay time of ICs due to Cu's low resistivity characteristic.

To form Cu-embedded interconnection, a technique called “damascening” is being used.

Damascening process proceeds as follows: First, grooves are formed into the insulating film. Second, a barrier metal is deposited upon all over the insulating film. Then, a conductive film made of copper or other appropriate substance is deposited upon all aver the insulating film. Finally, the conductive film is polished by means of CMP to be embedded in the grooves of the insulating film.

There is also a technique called “dual damascening”. Dual damascening process enables the simultaneous formation of both an upper interconnection and contacts through via holes connecting the upper interconnection of the insulating film with an under interconnection. Dual damascening process proceeds as follows: First, not only grooves for interconnection, but also via holes are formed into an insulating film before forming a conductive film. Second, the conductive film is deposited all over the insulating to cover the grooves and the via holes. Finally, the conductive film is polished by means of CMP to be embedded into the grooves and via holes.

The control over the amount of polishing the conductive film should be complete and sufficiently accurate. If any conductive film on the surface of the insulating film remains, it may cause undesirable short-circuiting in the produced semiconductor device. Consequently, the device may fail in its tests or in its performances. If the polishing continues in excess beyond the point of the complete removal of the conductive film right upon the insulating film, an over etching of the conductive film occurs at the areas where the conductive film is exposed, and the effect of so called “dishing” results. Often, the dishing effect increases the resistance of interconnection larger than the designed value, and/or causes unstable electrical contacts between interconnections.

Therefore, it is extremely desirable to create such a film right upon the insulating film that facilitates a clear, exact end-point detection during the process of polishing the conductive film deposited right upon such created film.

Likewise, it is extremely desirable, too, to form such a film that facilitates a clear, exact end-point detection when polishing with CMP technique the insulating film that was deposited in the trenches dug on the surface of the semiconductor substrate.

Even when such film remains in the semiconductor device to be produced, however, the film should not degrade any targeted characteristics of the semiconductor device.

### SUMMARY OF THE INVENTION

This invention has been made in view of above problem in the prior art and it is an object of the present invention to provide a method for forming a film of the semiconductor device that facilitate the exact end-point detection for the polishing process of conductive film or insulating film without compromising any of the desirable performance of the semiconductor device.

In the invented methods, Diamond Like Carbon (DLC) film is used during the process of either etching or polishing the insulating film, as not only the etching stopper, but also the polishing stopper, respectively.

Similarly, in the invented methods, DLC film is used during the process of either etching or polishing the conductive film, as not only the etching stopper, but also the polishing stopper, respectively.

The value of Spinel hardness of DLC film is 2,800, approximately, and is much larger than those of SiO₂ film's (800) or Si₃N₄ film's (1,200). Specifically, since the selectivity of etching SiO₂ with respect to etching DLC is very high, the DLC film has the exceptionally desirable characteristics as the stopper, for etching or polishing SiO₂ film.

The value of dielectric constant of DLC film is about 2.7, and is very low as compared to those values of SiO₂ film's (4.0) and Si₃N₄ film's (8.4). Hence, the propagation delay time of the signal transmitted through the interconnection is not affected at all effectively by the existence of such DLC film.

Further more, the leak current through the DLC film can be remarkably decreased, as it is exposed in a plasma gas containing fluorine after its formation. The gas mentioned in the previous sentence can be either one of such fluorine gases as C₂F₆, C₃F₈, NF₃, CF₄ or SF₆.

By said exposing operation, we can prevent any performance degradation of semiconductor device to be produced with the invented methods, even if the DLC film remains in the semiconductor device as a part of an insulating film, after it has been used as either the etching stopper or the polishing stopper.

Since, the DLC film can be used as the stopper of either etching or polishing not only the insulating film but also the conductive film, said DLC film is applicable to the formation of interconnection using dual damascening technique, also.

### BRIEF DESCRIPTION OF THE DRAWINGS

FIGS. 1A to 1D are sectional views for explaining the first and the second embodiment of the present invention. They are provided for explaining the methods to form films, in which the DLC film is used as etching stopper.

FIGS. 2A to 2F relate to the third embodiment of this invention. These figures are provided for explaining the methods to form films, in which the DLC film is used as etching stopper.

FIGS. 3A to 3F relate to the fourth embodiment of this invention. These figures are provided for explaining the methods to form films, in which the DLC film is used as etching stopper.

### DESCRIPTION OF THE PREFERRED EMBODIMENT

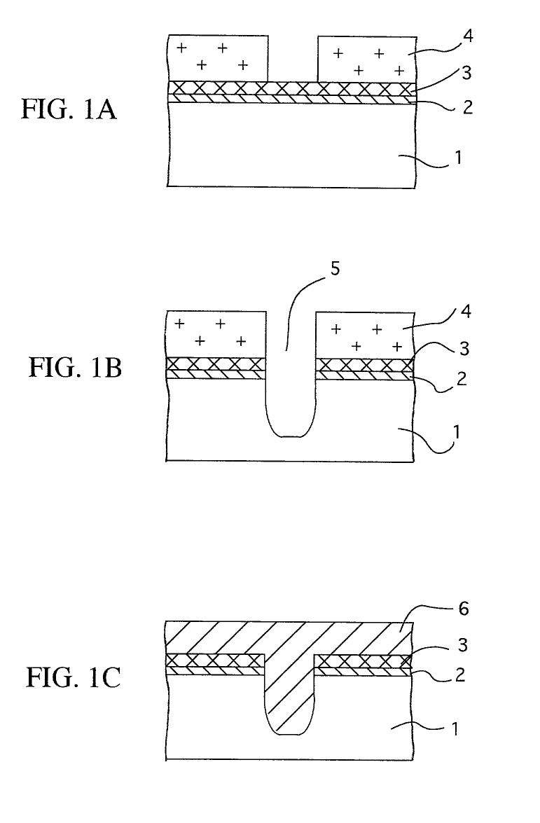

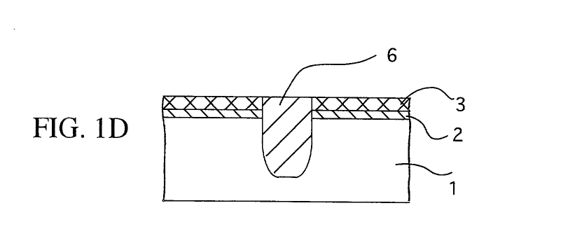

Embodiments of the present invention are explained hereinafter, referring to FIG. 1A to FIG. 3F.

(A) The First Embodiment

The first embodiment of the present invention relates to the method to embed the insulating film into trenches by making use of DLC (Diamond Like Carbon) film as the etching stopper.

As illustrated in FIG. 1A, the process proceeds as follows:

Firstly, a PAD SiO₂ film 2 of 10 nm in thickness is formed by using thermal oxidation upon a Si substrate 1.

Secondly, a DLC film 3 of 150 nm in thickness is deposited by using DC (Direct Current) plasma CVD(Chemical Vapor Deposition), electroplating, or sputtering.

As for the other methods for forming DLC film 3, micro wave plasma CVD and Ion Beam Sputtering are well used.

Thirdly, as shown in FIG. 1A, a resist film 4 is deposited and then a patterning of the resist film 4 is carried out by making use of a mask that is not shown in the figure.

Fourthly, a dry etching of the DLC film 3 is performed by using O₂ gas plasma as well as by using the patterned resist film 4 as the masking resist against the dry etching.

The condition of the dry etching is as follows, for example:

(1) to introduce O₂ gas into reactor chamber at the flow rate of 800 sccm,

(2) to set the gas pressure in the reactor chamber at 1 Torr,

(3) to set RF power for the plasma creation at 150 W,

(4) to apply an 150 W of low-frequency-bias power to Si substrate 1,

(5) to create the plasma O₂ gas with the foregoing conditions, and

(6) to expose the substrate in the plasma O₂ gas for 30 seconds.

With the condition described hereinbefore, the DLC film 3 can be etched off selectively.

Fifthly, the SiO₂ film 2 is etched off selectively with a wet etching method using a solution containing hydrofluoric acid or the like to be exposed the surface of the Si substrate 1.

Sixthly, the Si substrate 1 is etched with a dry etching method using a gas containing chlorine or the like. As the result of the dry etching, a trench 5 is formed at the surface of the Si substrate 1, as illustrated in FIG. 1B.

Seventhly, a SiO₂ film 6 is formed with CVD method as shown in FIG. 1C.

Eighthly, the SiO₂ film 6 is polished by using CMP method.

Finally, the polishing of the SiO₂ film 6 is stopped at the time when DLC film 3 appears at the surface of the substrate 1.

In this manner, the SiO₂ film 6 is embedded into the trench 5 to accomplish both of the surface planarization and the electrical isolation of the Si substrate 1 simultaneously.

The DLC film 3 which is formed in such a way, has the following characteristics:

(1) spinel hardness of around 2,800,

(2) no moisture absorbing tendency, and

(3) dielectric constant of around 2.7.

Since the value of Spinel hardness of DLC film is much larger than that of SiO₂ film which is around 800 or of Si₃N₄ film which is around 1,200, the etching selectivity of DLC film with respect to SiO₂ film is higher than the etching selectivity of Si₃N₄ with respect to the same. Spinel hardness is one criterion for the selectivity ratio in mechanical polishing. However we should take the selectivity ratio in chemical polishing into consideration, also, in order to evaluate the selectivity as a whole.

As far as the permitivity is concerned, the value of dielectric constant of DLC film is significantly smaller than that of SiO₂ film which is about 4.0 or Si₃N₄ film which is about 8.4. Consequently, DLC film can shorten the signal propagation delay caused by interconnection capacitance. Furthermore, the adhesion strength between DLC film and SiO₂ film is sufficiently strong.

(B) The Second Embodiment

The description of the second embodiment that relates to the method to embed an insulating film into trenches by making use of DLC film as the etching stopper, is given in this section.

The distinct point in the second embodiment from the first embodiment is the existence of the process in which the DLC film 3 is exposed in the plasma containing fluorine gas.

The actual condition of the plasma exposing process is as follows:

(1) to introduce NF₃ gas, after forming the DLC film 3 into reactor chamber at the flow rate of 200 sccm,

(2) to set the gas pressure in the reactor chamber at about 1 Torr,

(3) to set RF power for the plasma creation at about 150 W,

(4) to apply a 0 W of low-frequency-bias-power to Si substrate 1,

(5) to create the plasma of NF₃ gas with the foregoing conditions, and

(6) to expose the substrate in the plasma of NF₃ for 30 seconds.

As the result of the treatment described hereinbefore, the leak current through the DLC film 3 decreased to 1.5 pA/mm² from 0.5 nA/mm² of the leak current of the same before the plasma process.

The decrease of the leak current of DLC film is able to improve the performance of the semiconductor device. Accordingly, we are able to use the DLC film 3 as an insulating film even if it remains in the semiconductor device after it have been utilized as the etching stopper.

Though the gas used in the explanation given just hereinbefore, is NF₃, it can be either one of such fluorine gases as C₂F₆, C₃F₆, CF₄ or SF₆ instead.

(C) The Third Embodiment

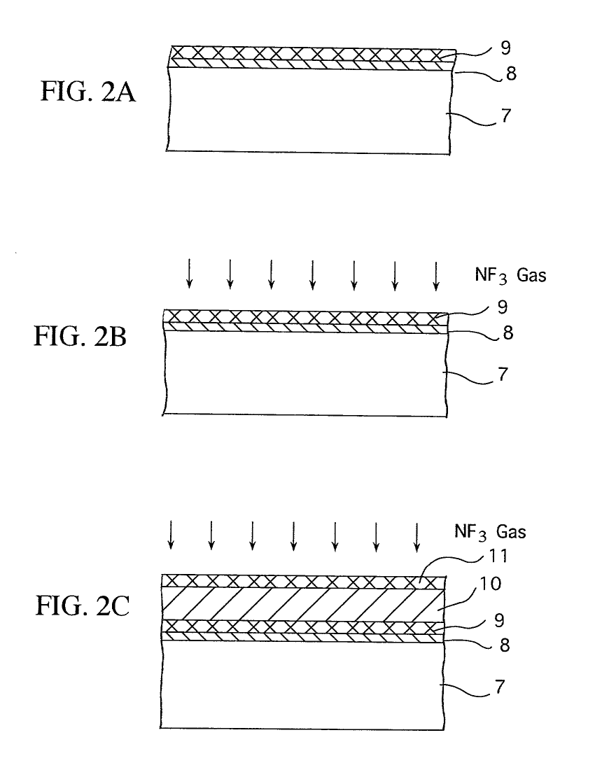

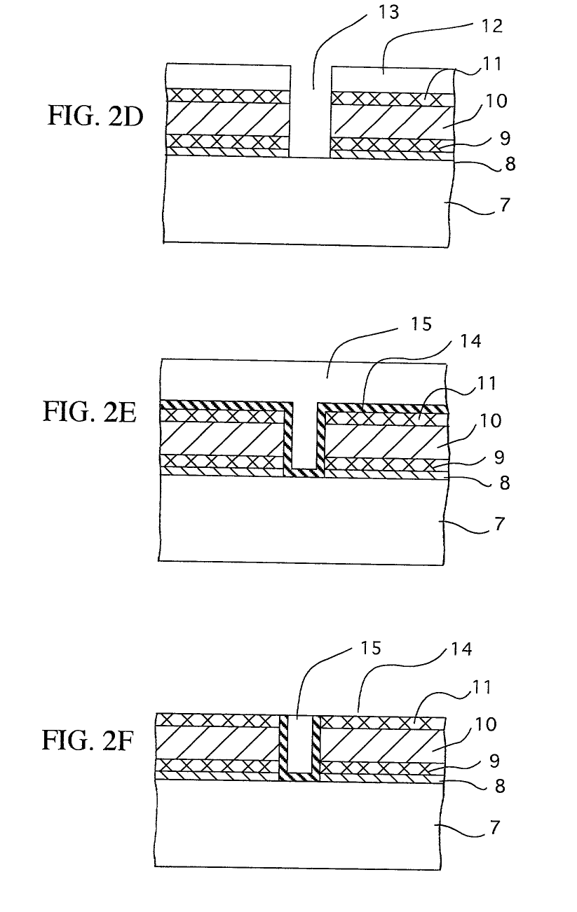

In this section, the description of the third embodiment that relates to the method to form Cu interconnection by means of single damascening technique at which DLC film is used as etching stopper is given referring to the FIGS. 2A to 2F.

Firstly, as shown in FIG. 2A, a PAD SiO₂ film 8 of 10 nm in thickness is formed upon a Si substrate 7 by means of thermal oxidation, then a DLC film 9 of 150 nm in thickness is formed thereupon. Secondly, as shown in FIG. 2B, the DLC film 9 is exposed in NF₃ plasma so as to improve the quality of the DLC film.

Thirdly, as shown in FIG. 2C, a SiO₂ film 10 is formed by CVD method, and then a DLC film 11 is formed thereupon. Fourthly, as shown in the same FIG. 2C, the DLC film 11 is exposed in NF₃ plasma in order to improve the quality of the DLC film.

Fifthly, as shown in FIG. 2D, a resist film 12 is deposited, and then the resist film 12 is patterned by making use of a mask that is not shown in the figure.

Sixthly, as shown in the same FIG. 2D, an opening 13 where the surface of the Si substrate 7 is exposed, is formed by etching the DLC film 11, the SiO₂ film 10, the DLC film 9 and the PAD SiO₂ film 8 off in turn, using the patterned resist film 12 as the masking resist against the etching.

Seventhly, the resist film 12 is removed from the entire surface of the substrate and then, as shown in FIG. 2E, a TiN film 14 is formed as the barrier film by using sputtering method.

Eighthly, as shown in the same FIG. 2E, a Cu film 15 is deposited so as to fill up the opening 13 at least by either one of such means as CVD, electroplating or sputtering.

Finally, as shown in FIG. 2F, the Cu film 15 as well as the TiN film 14 are polished by using CMP and the polishing is stopped at the point where DLC film 11 appears at the surface of the substrate. Thus, we can accomplish not only embedding the Cu film 15 into the opening 13, but also the surface planarization, simultaneously.

The existence of these DLC films greatly contributes to shortening the signal propagation delay of the semiconductor device by the following three facts:

(1)the quality of both DLC film 9 and DLC film 11 is improved through the invented process,

(2) the dielectric constant of DLC film is as low as 2.7, and

(3) they can remain existing in the semiconductor device to be produced upon and underneath the SiO₂ film 10, even after they had been used as the end point detector in the process of polishing the Cu film 15 by CMP method.

The interlayer insulating film used in the foregoing explanation is SiO₂ film, however, of course, it can be such an insulator made of either an organic substance or an inorganic substance instead, that may have a lower dielectric constant than that of SiO₂ in order to shorten the signal propagation delay time further.

The embodiment described in this section is applicable also to via contact which is to connecte the one interconnection on the interlayer insulating film to the other interconnection under the interlayer insulating film through the opening of the interlayer insulating film.

(D) The Fourth Embodiment

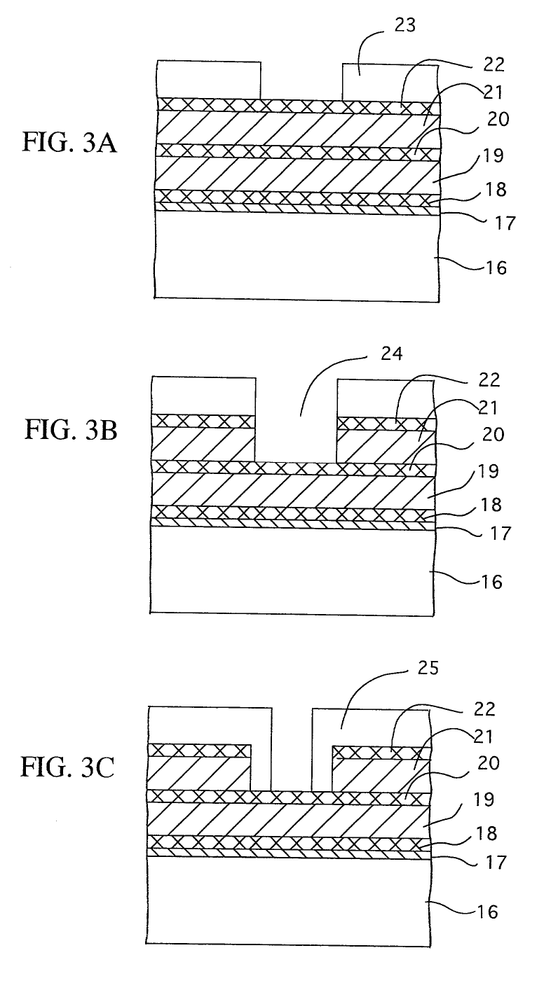

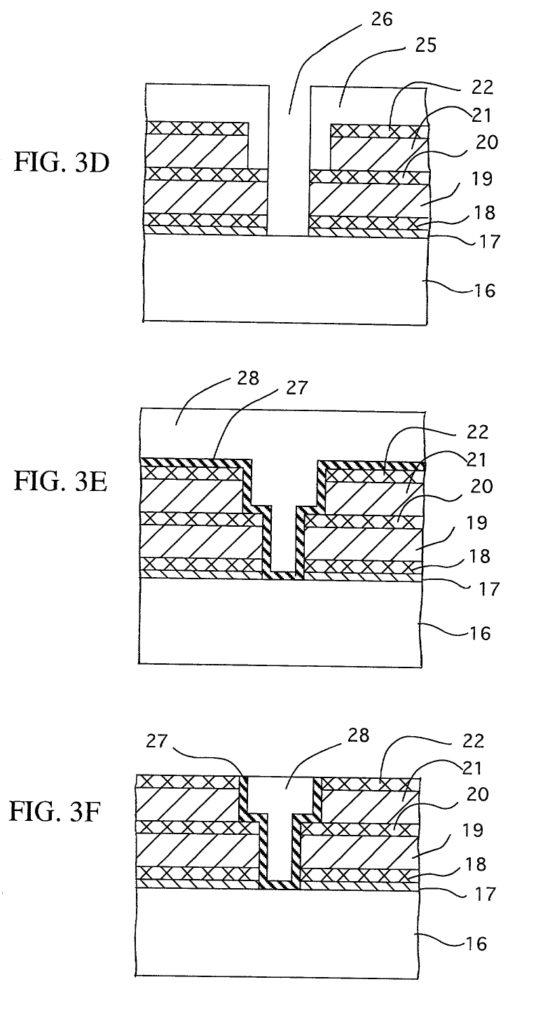

In this section, the description of the fourth embodiment that relates to the method to form Cu interconnection by means of dual damascening technique at which DLC film is used as etching stopper is given referring to the FIGS. 3A to 3F.

Firstly, as shown in FIG. 3A, a PAD SiO₂ film 17 of 10 nm in thickness is formed upon Si substrate 16 by means of thermal oxidation, and then a DLC film 18 of 150 nm in thickness is formed thereupon. Secondly, the quality of DLC film 18 is improved by exposing it in NF₃ plasma.

Thirdly, as shown in the same FIG. 3A, a SiO₂ film 19 of 500 nm in thickness is formed by CVD method, then a DLC film 20 150 nm in thickness is formed thereupon. Fourthly, the quality of DLC film 20 is improved by exposing it in NF₃ plasma.

Fifthly, as shown in the same FIG. 3A, a SiO₂ film 21 of 500 nm in thickness is formed by CVD method, then a DLC film 22 of 150 nm in thickness is formed thereupon. Sixthly, the quality of DLC film 22 is improved by exposing it in NF₃ gas. Seventhly, a resist film 23 is formed, then, as shown in the same FIG. 3A, a patterning of the resist film 23 is carried out by making use of a mask that is not shown in the figure.

Eighthly, as shown in FIG. 3B, grooves 24 for interconnection are formed by etching off both DLC film 22 and the SiO₂ film 21, using such patterned resist film 23 as the masking resist against the etching.

Ninthly, a resist film 25 is formed then, as shown in FIG. 3C, and a patterning of the resist film 25 is carried out by making use of a mask that is not shown in the figure.

Tenthly, as shown in FIG. 3D, an opening 26 that exposes the surface of the Si substrate 16 is formed by etching the DLC film 20, the SiO₂ film 19, the DLC film 18 and the PAD SiO₂ film 17 off.

Eleventhly, the resist film 25 is removed from the entire surface of the substrate, and then, as shown in FIG. 3E, a TiN film 27 is formed as the barrier film by sputtering method. Twelvethly, a Cu film 28 is deposited so as to fill up the opening 26 as well as grooves 24, by either one of such means as CVD, electroplating or sputtering

Finally, as shown in FIG. 3F, the Cu film 28 is polished as well as the TiN film 27 by means of CMP, until the point in time when the DLC film 22 appears, and the polishing at that point. Thus, we can accomplish not only embedding the Cu film 28 into both the opening 26 and the groove 24, but also the surface planarization simultaneously.

The existence of these DLC films greatly contributes to shortening the signal propagation delay of the semiconductor devices by the following three facts:

(1) the quality of the DLC film 18, the DLC film 20 and the DLC film 22 is improved through the invented process of gas plasma containing fluorine,

(2) the dielectric constant of those DLC films is as low as 2.7, and

(3) they remain existing in the semiconductor device to be produced, accompanied with SiO₂ film 19 and SiO₂ film 21, even after they had been used as the endpoint detector in the process of polishing the Cu film by CMP method.

(E) Other Embodiments

In the foregoing sections of this document, we described the invention in detail with respect to the each embodiment of the present invention. The claim of this invention is not limited to the embodiments described hereinbefore but the variations to the foregoing embodiments shall be included in the scope of this invention so long as the variations can be regarded within the extent of engineering changes to the each embodiment.

For example, the DLC film formed underneath a conductive film such as Cu (copper) can be utilized as etching stopper of the conductive film.

What is claimed is:

1. A method of forming a film of a semiconductor device comprising the steps of:
forming a DLC (Diamond Like Carbon) film;
forming an insulating film on said DLC film;
etching said insulating film selectively; and
stopping said etching at the point of a surface appearance of said DLC film.

2. A method of forming a film of a semiconductor device comprising the steps of:
forming a DLC film;
forming an insulating film on said DLC film;
etching said conductive film selectively; and
stopping said etching at the point of a surface appearance of said DLC film.

3. A method of forming a film of a semiconductor device comprising the steps of:
forming a DLC film;
exposing a plasma gas containing fluorine to said DLC film; and
forming an insulating film on said DLC film.

4. The method according to claim 3, wherein said gas containing fluorine is one selected from C₂F₆, C₃F₈, NF₃, CF₄ and SF₆.

5. The method according to claim 3, comprising the additional steps of etching said insulating film selectively, and stopping said etching at the point of a surface appearance of said DLC film.

6. The method according to claim 3 , comprising the additional steps of polishing said insulating film by CMP (Chemical Mechanical Polishing) method and stopping said polishing at the point of a surface appearance of said DLC film.

7. The method according to claim 3, wherein said DLC film for said stopping is remained to use as an insulating film of semiconductor device.

8. The method according to claim 4, wherein said DLC film for said stopping is remained to use as an insulating film of semiconductor device.

9. The method according to claim 5, wherein said DLC film for said stopping is remained to use as an insulating film of semiconductor device.

10. The method according to claim 6, wherein said DLC film for said stopping is remained to use as an insulating film of semiconductor device.

11. A method of forming a film of a semiconductor device comprising the steps of:
forming a DLC film;
exposing a plasma gas containing fluorine to said DLC film; and
forming a conductive film on said DLC film.

12. The method according to claim 11, wherein said gas containing fluorine is one selected from C₂F₆, C₃F₈, NF₃, CF₄ and SF₆.

13. The method according to claim 11, comprising the additional steps of etching said conductive film selectively, and stopping said etching at the point of a surface appearance of said DLC film.

14. The method according to claim 11, comprising the additional step of polishing said conductive film by method and stopping said polishing at the point of a surface appearance of said DLC film.

15. The method according to claim 11, wherein said DLC film for the stopping is remained to use as an insulating film of semiconductor device.

16. The method according to claim 12, wherein said DLC film for the stopping is remained to use as an insulating film of semiconductor device.

17. The method according to claim 13, wherein said DLC film for the stopping is remained to use as an insulating film of semiconductor device.

18. The method according to claim 14, wherein said DLC film for the stopping is remained to use as an insulating film of semiconductor device.
